(19) United States
(12) Patent Application Publication
(10) Pub. No.: US 2026/0322149 A1
(43) Pub. Date: Oct. 15, 2026

(54) BATTERY CHARGING METHOD AND APPARATUS

(71) Applicant: LG ENERGY SOLUTION, LTD., Seoul (KR)

(72) Inventors: Dong-In CHOI, Daejeon (KR); Tae-Soon PARK, Daejeon (KR); Ji-Eun LEE, Daejeon (KR)

(21) Appl. No.: 19/145,185

(22) PCT Filed: Jul. 22, 2024
(86) PCT No.: PCT/KR2024/010574

§ 371 Date: Jul. 1, 2025

(30) Foreign Application Priority Data
Jul. 27, 2023 (KR) 10-2023-0098508

(51) Int. Cl. H02J 7/82; H01M 10/44; H02J 7/90

(52) U.S. Cl. CPC H02J 7/82; H01M 10/44; H02J 7/927; H02J 7/933

(57) ABSTRACT

A battery charging method for charging a battery by dividing a charging process into a plurality of charging sections includes applying a first discharging pulse between an n−1th charging section and an nth charging section, where n is a natural number greater than or equal to 2; and applying a second discharging pulse between the nth charging section and an n+1th charging section, where a discharging rate of the second discharging pulse is less than a discharging rate of the first discharging pulse.

### CROSS-REFERENCE TO RELATED APPLICATIONS

The present application is a National Phase entry pursuant to 35 U.S.C. § 371 of International Application No. PCT/KR2024/010574, filed on Jul. 22, 2024, and claims the benefit of and priority to Korean Patent Application No. 10-2023-0098508 filed on Jul. 27, 2023 in the Republic of Korea, the disclosures of each which are incorporated herein by reference in their entireties for all purposes as if fully set forth herein.

### TECHNICAL FIELD

The present disclosure relates to a battery charging method and apparatus, and more specifically, to a battery charging method and apparatus capable of maximizing the charging efficiency of a battery by applying a discharging pulse to a charging process so that the environment in which the discharging pulse is applied is differentiated.

### BACKGROUND

As the demand for portable electronic products such as laptops, video cameras, and mobile phones that use electricity as a power source increases rapidly, and as mobile robots, electric bicycles, electric carts, and electric vehicles become more widely commercialized, research on high-performance secondary batteries that can be repeatedly charged and discharged is actively being conducted.

Commercialized secondary batteries include nickel-cadmium batteries, nickel-metal hydride batteries, nickel-zinc batteries, and lithium secondary batteries. Among them, lithium secondary batteries have the advantage of being free to charge and discharge and having a very low self-discharge rate compared to nickel-based secondary batteries, due to almost no memory effect. In addition, lithium secondary batteries have the characteristics of high energy density and high operating voltage, and thus are being studied more intensively than other types of secondary batteries and are being applied more widely in actual products.

Recently, secondary batteries have been widely used not only in small devices such as portable electronic devices, but also in medium and large-sized devices such as electric vehicles and energy storage systems (ESSs).

In this case, a battery module in which a number of electrically connected secondary batteries are stored together inside a module case is mainly used, and furthermore, when high power or large capacity is required, a battery pack in which a number of such battery modules are electrically connected is also used.

For secondary battery cells, cell assemblies, battery modules, or battery packs (hereinafter, collectively referred to as “batteries”), power efficiency and safety are important factors, so research is actively being conducted on battery management systems (BMS), which monitor the electrical characteristics of the battery and perform feedback control such as charging and discharging using the monitoring results.

Meanwhile, various studies are being conducted on battery charging, such as rapid charging, to more effectively reflect users' needs and improve the overall environment due to the high capacity of batteries.

The methods used to charge batteries include constant current-constant voltage (CC-CV) charging, pulse charging, boost charging, and multi-step CC charging.

When charging a battery in a high current environment to shorten the charging time, a lithium plating (Li-plating) phenomenon may occur in which lithium cations (Li⁺) supplied to the negative electrode are not quickly absorbed by the negative electrode and accumulate on the negative electrode and are precipitated as lithium metal.

This phenomenon causes side reactions with the electrolyte, changes in the kinetic balance of the battery, etc., and is the main cause of decreased battery performance, decreased capacity, and even deterioration or reduced lifespan of the battery.

In addition, if this phenomenon occurs, non-uniform lithium crystals (Li-dendrite) may be formed, which increases the possibility of a short circuit, which may lead to fatal safety problems such as fire and explosion.

### SUMMARY

Aspects of the present disclosure are designed to address the problems of the related art, and therefore embodiments of the present disclosure are directed to providing a battery charging method and apparatus that may fundamentally solve the problem of lithium precipitation and further optimize charging efficiency such as rapid charging by applying a discharging mode that applies a discharging pulse between charging sections divided into a plurality of sections so that the discharging environment of each discharging mode is differentiated.

The technical problems to be addressed by embodiments of the present disclosure are not limited to the above, and other problems not mentioned herein will be clearly understood by those skilled in the art from the following description.

A battery charging method according to an aspect of the present disclosure is a method of charging a battery by a charging process that is divided into a plurality of charging sections, and may include applying a first discharging pulse between an n−1th charging section and an nth charging section, where n is a natural number greater than or equal to 2; and applying a second discharging pulse between the nth charging section and an n+1th charging section.

A discharging rate of the second discharging pulse may be less than a discharging rate of the first discharging pulse.

A time during which the second discharging pulse is applied may be longer than a time during which the first discharging pulse is applied.

The discharging rate of the first or second discharging pulse and the time during which the first or second discharging pulse is applied may be set so that a discharging amount of the second discharging step is less than or equal to a discharging amount of the first discharging step.

A charging rate of the nth charging section may be less than a charging rate of the n−1th charging section.

Charging environments of the plurality of charging sections may be variably determined by a SOC value estimated based on a change in characteristic data of the battery according to charging.

The charging environments of the plurality of charging sections may include at least one of a length of each section of the plurality of charging sections and a charging rate of each section of the plurality of charging sections.

Discharging according to the first discharging section may be performed until a preset first condition is met, and discharging according to the second discharging section may be performed until a preset second condition is met, the first and second preset conditions including any of a discharging time and a state of charge (SOC) of the battery.

For each of the plurality of charging sections, charging may be performed until a target SOC is reached for each respective charging section.

A state of charge (SOC) of the battery after the n+1th charging section may be greater than a state of charge (SOC) of the battery after the nth charging section, for each of the plurality of charging sections performed in the charging process.

A battery charging apparatus according to another aspect of the present disclosure may comprise a charging unit configured to charge a battery; a discharging unit configured to discharge the battery; and a control unit configured to control the charging unit so that the battery is charged with a plurality of charging sections, and to control the discharging unit so that a first discharging pulse is applied between an n−1th charging section and an nth charging section, where n is a natural number greater than or equal to 2, and a second discharging pulse is applied between the nth charging section and an n+1th charging section.

The control unit may be configured to control the discharging unit so that a discharging rate of the second discharging pulse is less than a discharging rate of the first discharging pulse.

The control unit may be configured to control the discharging unit so that a time during which the second discharging pulse is applied is longer than a time during which the first discharging pulse is applied.

The control unit may be configured to control the discharging rate of the first or second discharging pulse and the time during which the first or second discharging pulse is applied so that a discharging amount of the second discharging pulse is less than or equal to a discharging amount of the first discharging pulse.

The control unit may be configured to control the charging unit so that a charging rate of the nth charging section is less than a charging rate of the n−1th charging section.

The control unit may be configured to control the charging unit so that charging environments of the plurality of charging sections are variably set using a preset target SOC.

The target SOC may be estimated as a SOC value at which lithium is precipitated based on a change in characteristic data of the battery according to charging.

The control unit may be configured to control the charging unit by setting charging environments of the plurality of charging sections that include at least one of a length of each section of the plurality of charging sections and a charging rate of each section of the plurality of charging sections.

The control unit may be configured to control the discharging unit so that discharging according to the first discharging section is performed until a preset first condition is met, and discharging according to the second discharging section is performed until a preset second condition is met, the first and second preset conditions including any of a discharging time and a state of charge (SOC) of the battery.

The control unit may be configured to control the charging unit, so that for each of the plurality of charging sections, charging is performed until a target SOC is reached for each respective charging section.

The control unit may be configured to control the charging unit so that a state of charge (SOC) of the battery after the n+1th charging section is greater than a state of charge (SOC) of the battery after the nth charging section, for each of the plurality of charging sections performed.

According to aspects of the present disclosure, by dividing charging into a plurality of sections and applying a discharging processing that applies a discharging pulse between the charging sections, lithium precipitation may be minimized and the precipitated lithium may be removed more effectively.

In addition, according to one aspect of the present disclosure, by differentially applying the discharging environment, specifically the time at which the discharging pulse is applied and the discharging rate of the discharging pulse in a sequential discharging processing of each other performed in time series, the charging efficiency may be further improved, such as reduction of the charging time, and also the operating performance or durability of the battery may be further improved by delaying or slowing down the aging process of the battery.

Furthermore, according to one aspect of the present disclosure, by organically grafting the electrical characteristic data of the battery and variably setting the charging environment of each charging section that is divided into a plurality of sections and performed, a charging environment optimized for the state of the battery that changes over time may be implemented.

### DESCRIPTION OF DRAWINGS

The accompanying drawings illustrate one or more preferred embodiments of the present disclosure and together with the foregoing disclosure, serve to provide further understanding of the technical features of the present disclosure, and thus, the present disclosure is not construed as being limited to the drawings.

FIG. 1 is a block diagram showing a detailed configuration of a battery charging apparatus according to an embodiment of the present disclosure.

FIG. 2 is a block diagram showing a detailed configuration of a data operation unit according to an embodiment of the present disclosure.

FIG. 3 is a flowchart showing a process according to an embodiment of the present disclosure.

FIG. 4 is a flowchart showing a process according to another embodiment of the present disclosure.

FIG. 5 is a drawing explaining an embodiment of a discharging rate of a discharging pulse for each discharging section according to an embodiment of the present disclosure.

FIG. 6 is a drawing explaining an embodiment of the time at which the discharging pulse is applied for each discharging section according to an embodiment of the present disclosure.

FIGS. 7 and 8 are drawings explaining time-series characteristics of a discharging environment for each discharging section based on the entire charging process according to an embodiment of the present disclosure.

FIG. 9 is a drawing explaining the process of determining a SOC at which lithium is precipitated during charging according to an embodiment of the present disclosure.

FIG. 10 is a drawing showing the performance results of a battery according to an embodiment of the present disclosure based on the discharge capacity retention.

### DETAILED DESCRIPTION

Hereinafter, preferred embodiments of the present disclosure will be described in detail with reference to the accompanying drawings. Prior to the description, it should be understood that the terms used in the specification and the appended claims should not be construed as limited to general and dictionary meanings, but interpreted based on the meanings and concepts corresponding to technical aspects of the present disclosure on the basis of the principle that the inventor is allowed to define terms appropriately for the best explanation.

Therefore, the description proposed herein is just a preferable example for the purpose of illustrations only, not intended to limit the scope of the disclosure, so it should be understood that other equivalents and modifications could be made thereto without departing from the scope of the disclosure.

Additionally, in describing the present disclosure, when it is deemed that a detailed description of relevant known elements or functions renders the key subject matter of the present disclosure ambiguous, the detailed description is omitted herein.

Throughout the specification, when a portion is referred to as “comprising” or “including” any element, it means that the portion may include other elements further, without excluding other elements, unless specifically stated otherwise.

Furthermore, the term “processor” described in the specification refers to a unit that processes at least one function or operation, and may be implemented by hardware, software, or a combination of hardware and software.

In addition, throughout the specification, when a portion is referred to as being “connected” to another portion, it is not limited to the case that they are “directly connected”, but it also includes the case where they are “indirectly connected” with another element being interposed between them.

FIG. 1 is a block diagram showing a detailed configuration of a battery charging apparatus 100 according to an embodiment of the present disclosure.

As illustrated in FIG. 1, the battery charging apparatus 100 according to embodiments of the present disclosure may be configured to include an interface unit 110, a charging unit 120, a discharging unit 130, a control unit 140, and a detecting unit 160.

Prior to the detailed description of embodiments of the present disclosure, the battery charging apparatus 100 according to embodiments of the present disclosure may be implemented through various combinatorial applications of electronic components, parts, etc., such as storage means, operation processing means, and input/output means (ASIC, chipset, logic circuit, register, communication modem, MCU, etc.).

Therefore, each component of the battery charging apparatus 100 illustrated in FIG. 1 should be understood as a functionally or logically distinct component rather than necessarily a physically distinct component.

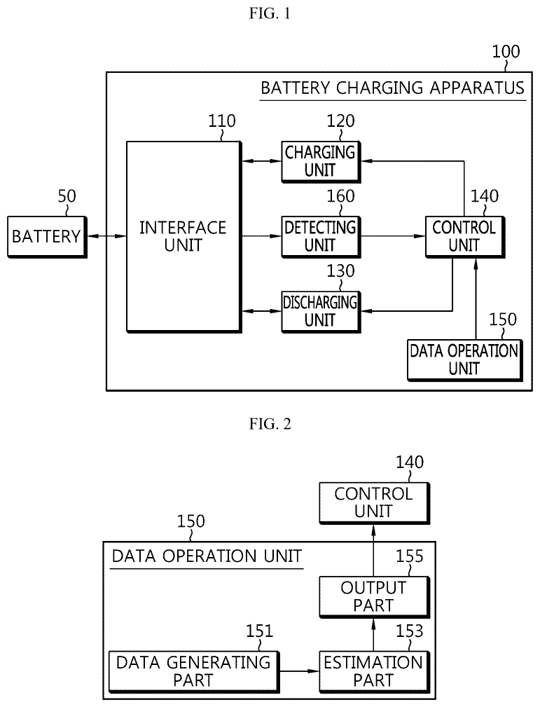

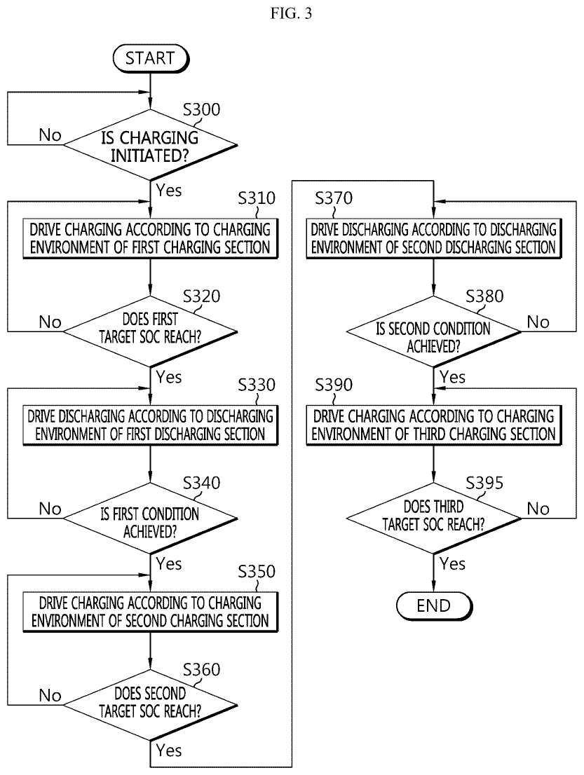

That is, since each component depicted in the drawings corresponds to a logical structure for effectively explaining the technical idea by the present disclosure, even if each component is configured integrated or separately, if the function performed by the logical structure of the present disclosure can be realized, it should be interpreted as being within the scope of the present disclosure, and if it is a component that performs the same or similar function, it should of course be interpreted as being within the scope of the present disclosure regardless of the consistency in their names. The same applies to the data operation unit 150 illustrated in FIG. 2.

In addition, the battery charging method of embodiments of the present disclosure may be implemented as a set of processing instructions or an algorithm for data processing, handling, control, calculation, etc. as a whole, and thus, it may be implemented by a combination of the logical configurations shown in FIG. 1, as well as in the form of software installed and operated on a computer or a terminal, module, etc. equivalent thereto.

For example, the battery charging method may be applied to a BMS (Battery Management System). When the BMS is connected to a charging device, the battery may be rapidly charged by controlling charging and discharging of the battery using the battery charging method according to an embodiment of the present disclosure.

As another example, the battery charging method may be applied to a charging device. The charging device may rapidly charge a battery using the battery charging method according to an embodiment of the present disclosure.

The charging unit 120 of the present disclosure may be electrically connected to the battery 50 and perform charging processing for the battery 50. According to an embodiment, the charging unit 120 of the present disclosure may be electrically connected to the battery 50 through an interface unit 110 linked to a physical means such as a jack or a socket, as illustrated in FIG. 1.

Since various types of secondary battery cells, cell banks, cell assemblies, cell modules, and battery packs may be targets of charging, the battery 50 in the following description may mean an object that collectively refers to cells, cell banks, cell assemblies, cell modules, and battery packs.

The discharging unit 130 according to embodiments of the present disclosure is configured to perform discharging on the battery 50, and may be electrically connected to the battery 50 through the interface unit 110, like the charging unit 120 described above, and of course, may be electrically connected to the battery 50 through an interface unit independent of the charging unit 120 depending on the embodiment.

The control unit 140 according to embodiments of the present disclosure is configured to be communicatively connected to the charging unit 120 and the discharging unit 130 and to control charging processing performed by the charging unit 120 and discharging processing performed by the discharging unit 130.

The battery charging apparatus 100 according to embodiments of the present disclosure is configured to charge the battery 50 by dividing the charging process into k sections (where k is a natural number greater than or equal to 2) without performing continuous charging from the start of charging to the end of charging (hereinafter referred to as ‘multi-step charging mode’).

The battery charging apparatus 100 according to embodiments of the present disclosure is configured to charge a battery by dividing the charging process into a plurality of charging sections, so that a first discharging pulse is applied between the n−1th (where n is a natural number greater than or equal to 2) charging section and the nth charging section and a second discharging pulse is applied between the nth charging section and the n+1th charging section.

However, in one embodiment, the discharging pulse may not always be applied between each charging section. For example, if the first discharging pulse is applied between the n−1th charging section and the nth charging section, the second discharging pulse may not be applied between the nth charging section and the n+1th charging section. Also, the third discharging pulse may be applied between the n+1th charging section and the n+2th charging section.

First, the overall charging process performed by embodiments of the present disclosure will be described, and the specific details of each discharging mode or discharging processing performed by applying a discharging pulse will be described later.

FIG. 3 is a flowchart illustrating the process of charging according to aspects of the present disclosure, and illustrates the process of performing charging based on an embodiment in which the charging process is divided into three charging sections.

According to certain embodiments, when a physical connection is made between the battery 50 and the charging unit 120 (or the interface unit 110), if charging is initiated by a method such as inputting an electrical signal or selecting a button or interface for initiating charging (S300), the control unit 140 of the present disclosure controls the charging unit 120 so that charging is driven according to the charging environment of the first charging section (S310).

The charging environment refers to the time at which charging is performed, that is, one or more of the length of the corresponding charging section, the size of the charging current, and the charging rate. It is preferable that the charging environment is variably set to reflect the current state of the battery 50, as described below. In the case of a multi-step charging method, it is preferable that the size of the charging current or the charging rate is set to decrease as it goes to a subsequent charging section.

According to certain embodiments, when the SOC (State of Charge) of the corresponding battery 50 reaches the first target SOC by charging of the first charging section (hereinafter referred to as the ‘first charging process’), the first charging process is terminated (S320). Depending on the embodiment, the condition for terminating the first charging process may be determined by whether the charging voltage of the battery 50 reaches the first threshold voltage, in addition to whether the SOC of the battery 50 reaches the first target SOC as described above.

After that, the control unit 140 according to embodiments of the present disclosure controls the discharging unit 130 to drive discharging according to the discharging environment of the first discharging mode for the battery 50 for which the first charging process is completed (S330). The discharging environment means at least one of the size of the discharging pulse, the discharging rate of the discharging pulse, and the time at which the discharging pulse is applied.

According to certain embodiments, when the discharging of the first discharging mode (hereinafter referred to as the ‘first discharging process’) satisfies the preset first condition (discharging time or current SOC of the battery 50, etc.) (S340), the control unit 140 of the present disclosure controls the discharging unit 130 to terminate the first discharging process, and then controls the charging unit 120 to initiate charging according to the second charging section (second charging process) (S350).

As explained above, the second charging process is also driven by a charging environment (one or more of the length of the charging section, the size of the charging current, and the charging rate) that is uniquely set in the second charging section itself.

According to certain embodiments, when the SOC of the battery 50 reaches the second target SOC through charging by the second charging process (S360), the control unit 140 of the present disclosure controls the charging unit 120 to terminate the second charging process, and controls the discharging unit 130 to drive discharging according to the discharging environment of the second discharging mode (S370).

According to certain embodiments, when the discharging of the second discharging mode (hereinafter referred to as the ‘second discharging process’) satisfies the preset second condition (discharging time or current SOC of the battery 50, etc.) (S380), the control unit 140 of the present disclosure controls the discharging unit 130 to terminate the second discharging process and controls the charging unit 120 to initiate the charging according to the third charging section (third charging) (S390).

When the SOC of the battery 50 reaches the third target SOC through charging by the third charging process (S395), the entire charging processing according to embodiments of the present disclosure is terminated.

FIG. 3 is a process according to an embodiment of the present disclosure, and it can be understood that charging may be performed by dividing the charging process into more charging sections depending on the embodiment. In the case of dividing the charging process into more charging sections, according to certain embodiments, discharging may be performed by applying a discharging pulse between at least two charging sections among the charging sections, and a resting period for a predetermined time may be applied between charging sections to which discharging processing is not applied to eliminate lithium precipitation.

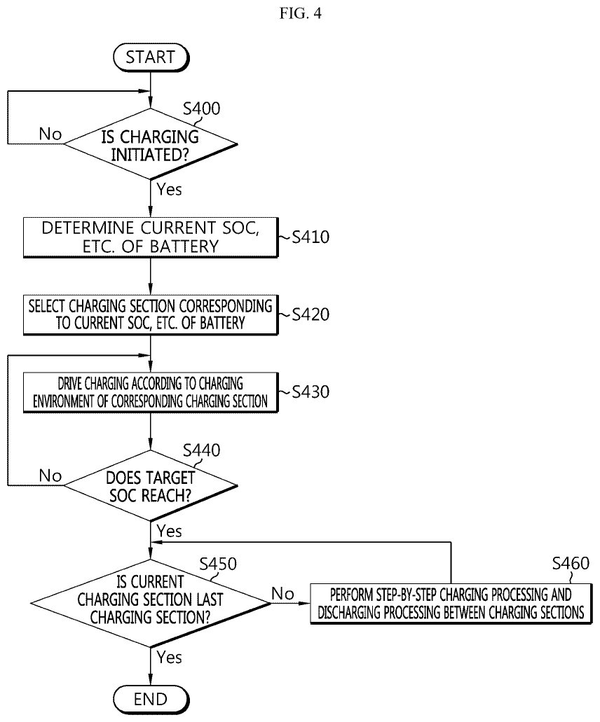

FIG. 4 is a flowchart showing a process according to another embodiment of the present disclosure.

The embodiment of the present disclosure described with reference to FIG. 3 above corresponds to an embodiment in which charging is performed with a battery 50 that is completely discharged or equivalent thereto, or charging is performed with a battery 50 having a lower SOC.

The embodiment illustrated in FIG. 4 corresponds to an embodiment in which the current SOC of the battery 50 is determined, which is a target of charging, and charging is performed by setting the charging section corresponding to the current SOC of the battery 50 among the plurality of charging sections as an initiation section of charging.

As described above, according to certain embodiments, when a signal, etc. for charging initiation is input (S400), the detecting unit 160 of the present disclosure determines the current SOC of the battery 50 using the electrical characteristic values (voltage, etc.) of the battery 50 (S410), and outputs the result data to the control unit 140 according to embodiments of the present disclosure.

According to certain embodiments, when data on the current SOC of the battery 50 is input, the control unit 140 of the present disclosure selects a charging section corresponding to the current SOC among the plurality of preset charging sections (S420), and controls the charging unit 120 to initiate charging with the charging environment (charging rate, size of charging current, etc.) of the selected charging section (S430).

After the SOC of the battery 50 reaches the target SOC according to the corresponding charging section (S440), if the charging section that has been performed is not the last charging section among the preset plurality of charging sections (S450), step-by-step charging and discharging processing between charging sections are cyclically performed as described with reference to FIG. 3, etc. (S460).

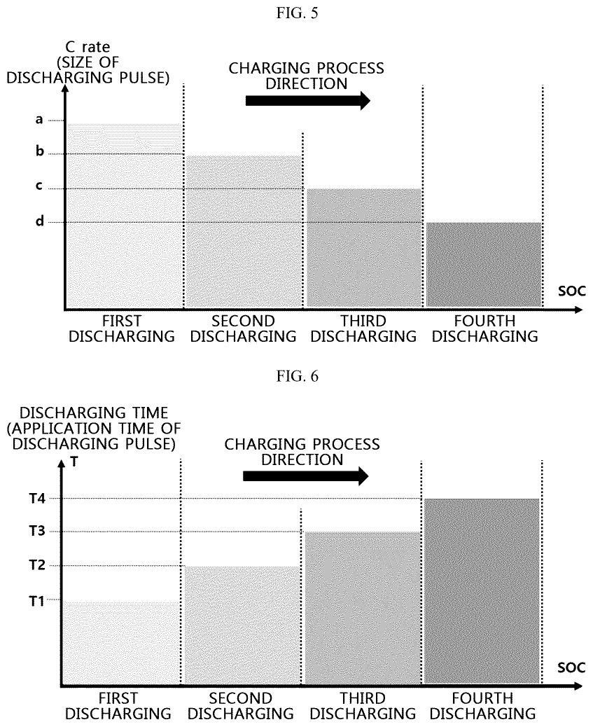

FIG. 5 is a drawing explaining an embodiment of a discharging rate of a discharging pulse for each discharging section, and FIG. 6 is a drawing explaining an embodiment of the time at which the discharging pulse is applied for each discharging section.

The embodiment illustrated in FIG. 5 corresponds to an embodiment in which four discharging processes are applied overall while the SOC of the battery 50 increases by charging.

Assuming that no discharging process is applied after the last charging section, this embodiment may correspond to an embodiment that in which the battery 50 is charged with five or more charging sections. Assuming that all discharging processes are applied between the current charging section and the next charging section, based on the time series order of charging, the first discharging process is applied between the first charging process and the second charging process, the second discharging process is applied between the second charging process and the third charging process, the third discharging process is applied between the third charging process and the fourth charging process, and finally, the fourth discharging process is applied between the fourth charging process and the fifth charging process.

As illustrated in FIG. 5, it is preferable that the discharging rate (C-rate) of the first discharging pulse applied in the first discharging process (discharging of the first discharging mode) is set to be the largest, and the discharging rate of the second discharging pulse applied in the second discharging process subsequent to the first discharging process is smaller than the discharging rate of the first discharging pulse. In addition, it is preferable that the discharging rate of the corresponding discharging mode gradually decreases as it goes to the third discharging process and then the fourth discharging process based on the time series order.

Based on the example of FIG. 5, b (discharging rate of the second discharging process) is smaller than a (discharging rate of the first discharging process) and larger than c (discharging rate of the third discharging process). In addition, it is preferable that d (discharging rate of the fourth discharging process) is smaller than c.

Specifically, it is preferable that the discharging rate of the first discharging pulse applied between the n−1th (where n is a natural number greater than or equal to 2) charging section and the nth charging section is greater than the discharging rate of the second discharging pulse applied between the nth charging section and the n+1th charging section. That is, it is preferable that the discharging rate of the second discharging pulse is less than the discharging rate of the first discharging pulse.

When configured in this way, the removal of lithium precipitated by charging of the corresponding charging section may be further accelerated, thereby more effectively suppressing performance deterioration of the battery 50.

Depending on the embodiment, as shown in FIG. 6, it is preferable that the discharging time (the time at which the discharging pulse is applied (the time at which discharging is performed)) of the subsequent discharging mode is greater than or equal to the discharging time of the previous discharging mode based on the time series order. For example, the discharging time of the current discharging mode may be equal to or greater than the discharging time of the previous discharging mode.

Based on the example of FIG. 6, T2 (the time at which the second discharging process is performed) is longer than T1 (the time at which the first discharging process is performed) and shorter than T3 (the time at which the third discharging process is performed). In addition, it is preferable that T4 (the time at which the fourth discharging process is performed) is longer than T3. However, although the embodiment of FIG. 6 illustrates an embodiment in which the discharging time of the nth discharging process exceeds the discharging time of the n−1th discharging process, as described above, an embodiment in which the discharging time of the nth discharging process is equal to the discharging time of the n−1th discharging process may also be applied.

Specifically, it is preferable that the application time of the first discharging pulse applied between the n−1th (where n is a natural number greater than or equal to 2) charging section and the nth charging section is shorter than or equal to the application time of the second discharging pulse applied between the nth charging section and the n+1th charging section. In other words, it is preferable that the application time of the second discharging pulse is longer than or equal to the application time of the first discharging pulse.

When configured in this manner, the removal of lithium precipitated by charging of the charging section may be induced more stably, thereby improving the charging efficiency of the battery 50 and effectively suppressing performance deterioration of the battery 50.

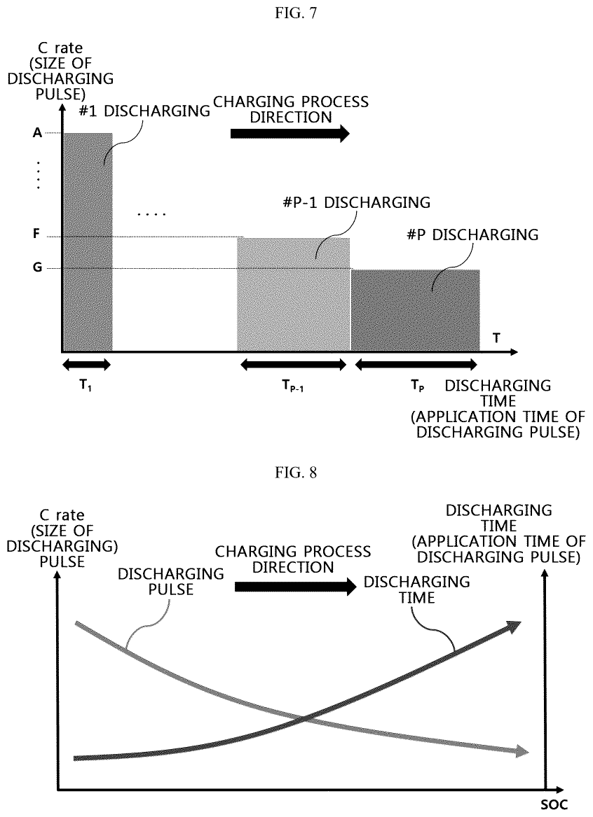

FIGS. 7 and 8 are drawings explaining time-series characteristics of a discharging environment for each discharging section based on the entire charging process, according to certain embodiments.

In the embodiments of FIGS. 7 and 8, considering the charging progress direction, it is preferable that the size (discharging rate) of the discharging pulse of the discharging mode becomes smaller as it progresses to the subsequent discharging mode.

In addition, in the embodiment of FIGS. 7 and 8, considering the charging progress direction, it is preferable that the time at which the discharging pulse of the discharging mode is applied is the same or longer as it goes to a subsequent discharging mode. More preferably, it is preferable that the time at which the discharging pulse is applied becomes longer as it goes to a subsequent discharging mode.

Depending on the embodiment, it is preferable that the discharging rate of the discharging pulse and the application time of the discharging pulse are set so that the discharging amount of each discharging mode is the same or decreases as it progresses to a subsequent discharging mode.

For example, based on the embodiment illustrated in FIG. 7, the discharging amount of the first discharging process may be defined by the multiplication operation of the discharging rate (A) of the discharging pulse and the application time (T1) of the discharging pulse, so the discharging environment (the discharging rate of the discharging pulse and the application time of the discharging pulse) of each discharging mode may be set as a condition that satisfies Formula 1 below.

$$A \times {T}_{1} \geq ⋯ \geq F \times {T}_{P - 1} \geq G \times {T}_{P} \qquad [ Formula 1 ]$$

In this respect, the control unit 140 of the present disclosure may be configured to control the discharging rate of the first or second discharging pulse and the time at which the first or second discharging pulse is applied so that the discharging amount of the second discharging pulse is less than or equal to the discharging amount of the first discharging pulse.

As described above, the first discharging pulse means a discharging pulse applied between the n−1th (where n is a natural number greater than or equal to 2) charging section and the nth charging section, and the second discharging pulse means a discharging pulse applied between the nth charging section and the n+1th charging section.

According to certain embodiments, the control unit may be configured to control the charging unit so that the charging environments of the plurality of charging sections may be variably set using a preset target SOC.

Here, the charging environment of the charging section means one or more of the length of the charging section (the time at which charging is performed), the size of the charging current, and the charging rate.

Specifically, the target SOC may be estimated as a SOC value at which lithium is precipitated based on the change in characteristic data of the battery according to charging.

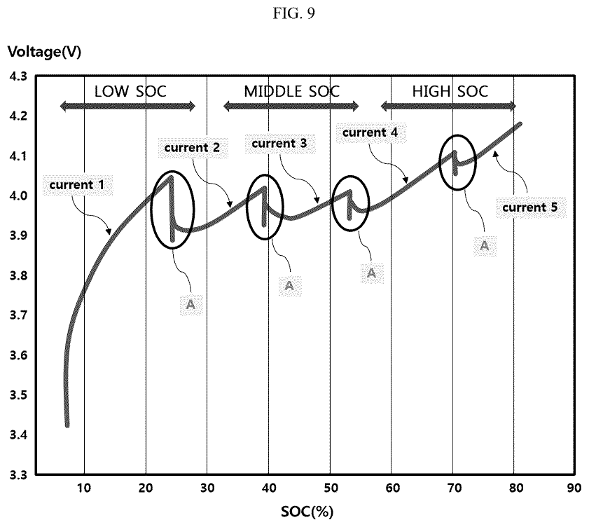

FIG. 9 is a profile showing the relationship between the SOC and voltage of the battery 50 in relation to charging, according to certain embodiments. Specifically, the embodiment of FIG. 9 is a charging profile showing the corresponding relationship between the SOC and voltage of the battery when the battery is charged in a multi-step charging method according to an embodiment of the present disclosure.

More specifically, the embodiment of the present disclosure that sets up a plurality of charging sections, etc. by organically reflecting the current state (deterioration level, SOH (State of health), etc.) of the battery 50 will be explained in detail.

FIG. 2 is a block diagram showing a detailed configuration of the data operation unit 150, according to one embodiment.

Referring to FIG. 2, according to certain embodiments, the data operation unit 150 may be configured to include a data generating part 151, an estimation part 153, and an output part 155, and corresponds to a configuration that estimates a SOC value at which lithium is precipitated during a charging process and outputs data thereon to the control unit 140 of the present disclosure.

According to certain embodiments, when the target SOC that is estimated as the SOC value at which lithium is precipitated is input to the control unit 140, the control unit 140 may variably set the charging environments of a plurality of charging sections based on the target SOC. In addition, the control unit 140 may control the charging unit 120 and the discharging unit 130 based on the target SOC.

According to certain embodiments, the data generating part 151, which may be a component of the data operation unit 150, may be configured to generate characteristic data of the battery 50 according to charging. The characteristic data may include the voltage of the battery 50, the voltage change rate, the voltage increase rate (slope value), the change rate of the voltage increase rate (change rate of the slope value), etc.

The target battery 50 for which characteristic data is generated may be a non-degenerated battery (e.g., a BOL (Beginning of life) battery) with specifications equivalent to those of the battery 50 currently being charged, as well as multiple batteries classified by SOH.

According to certain embodiments, when the characteristic data is generated, the estimation part 153 of the present disclosure estimates the target SOC (A, FIG. 9) at which lithium is precipitated based on the characteristic data or the change in characteristic data, and the output part 155 of the data operation unit 150 outputs the target SOC to the control unit 140. Of course, the target SOC (A) may be plural as shown in FIG. 9.

According to certain embodiments, when the target SOC is input in this way, the control unit 140 variably sets the points at which the charging environment and discharging mode of the plurality of charging sections are applied using multiple target SOCs. It is desirable that the target SOC, as well as the setting data for the charging environment determined by the target SOC, is utilized to be organized into a database linked to the deterioration degree of the battery 50.

In the embodiment of FIG. 1, the data operation unit 150 is described as being included in the battery charging apparatus 100 according to an embodiment of the present disclosure. However, the data operation unit 150 may be configured as a separate device provided externally to the battery charging apparatus 100. In this case, the data operation unit 150 may be connected to the control unit 140 via wired and/or wireless communication, and may transmit information about the target SOC to the control unit 140. For example, the data operation unit 150 may be a cloud computing device that estimates the target SOC for each battery by considering the degree of degradation of the battery, etc., and stores the estimated target SOC in a database.

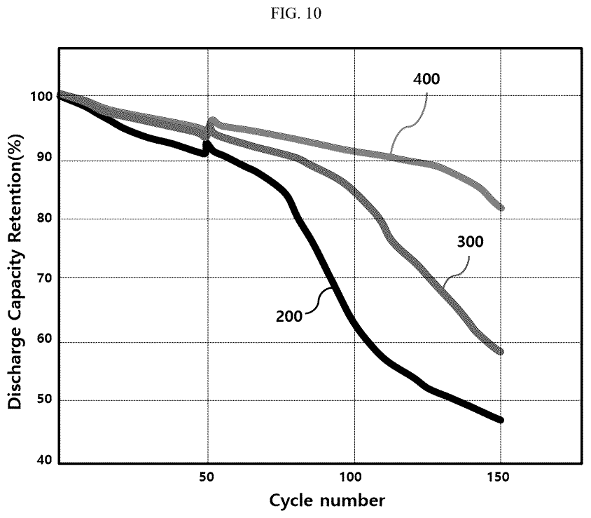

FIG. 10 is a diagram showing the performance results of a battery according to the embodiment of the present disclosure based on the discharge capacity retention. As is well known, a battery has a behavioral characteristic in which its discharge capacity retention decreases as use (charging and discharging) continues or is repeated.

In FIG. 10, 200 is an example of a behavior characteristic graph of a battery to which only a common condition is applied that charges at a charging rate (charging current size) that decreases as it proceeds to a subsequent charging section. In FIG. 10, 300 is a behavior characteristic graph of a battery to which a condition that a discharging pulse between charging sections is applied so that a discharging pulse having the same discharging rate and the same discharging pulse is applied for the same time to all discharging modes is applied together with the common condition. In FIG. 10, 400 is a behavior characteristic graph of a battery to which a condition that a discharging pulse is applied between charging sections so that the discharging rate decreases and the time at which the discharging pulse is applied becomes longer as it proceeds to a subsequent discharging mode is applied together with the common condition.

As shown in FIG. 10, in the case of 400, to which processing by a preferred embodiment of the present disclosure is applied, it may be confirmed that the durability and performance maintenance rate of the battery 50 itself are clearly improved as the performance degradation is significantly delayed or slowed down compared to 200 and 300.

The present disclosure has been described in detail. However, it should be understood that the detailed description and specific examples, while indicating preferred embodiments of the disclosure, are given by way of illustration only, since various changes and modifications within the scope of the disclosure will become apparent to those skilled in the art from this detailed description.

The drawings or the like attached for explaining the present disclosure and illustrating examples thereof may be illustrated in a somewhat exaggerated form in order to emphasize or highlight the technical content of the present disclosure. However, it should be interpreted that it is obvious that various modified examples are possible at the level of a person skilled in the art by considering the previously described content and matters illustrated in the drawings.

In addition, it is self-evident that expressions such as first, second, upper, lower, or top and bottom in the explanation of the present disclosure are merely instrumental concept terms used to relatively distinguish components (elements) from each other, and are not terms used to indicate a specific order, priority, or the like, or terms used to physically distinguish each component (element) on an absolute basis.

### EXPLANATION OF REFERENCE SIGNS

100: battery charging apparatus
110: interface unit
120: charging unit
130: discharging unit
140: control unit
150: data operation unit
151: data generating part
153: estimation part
155: output part
160: detecting unit

1. A battery charging method for charging a battery by a charging process that is divided into a plurality of charging sections, the battery charging method comprising:
applying a first discharging pulse between an n−1th charging section and an nth charging section, where n is a natural number greater than or equal to 2; and
applying a second discharging pulse between the nth charging section and an n+1th charging section,
wherein a discharging rate of the second discharging pulse is less than a discharging rate of the first discharging pulse.

2. The battery charging method according to claim 1,
wherein a time during which the second discharging pulse is applied is longer than a time during which the first discharging pulse is applied.

3. The battery charging method according to claim 2,
wherein the discharging rate of the first or second discharging pulse and the time during which the first or second discharging pulse is applied are set so that a discharging amount of the second discharging step is less than or equal to a discharging amount of the first discharging step.

4. The battery charging method according to claim 1,
wherein a charging rate of the nth charging section is less than a charging rate of the n−1th charging section.

5. The battery charging method according to claim 1,
wherein charging environments of the plurality of charging sections are variably determined by a state of charge (SOC) value estimated based on a change in characteristic data of the battery according to charging.

6. The battery charging method according to claim 5,
wherein the charging environments of the plurality of charging sections include at least one of a length of each section of the plurality of charging sections and a charging rate of each section of the plurality of charging sections.

7. A battery charging apparatus comprising:
a charging unit configured to charge a battery;
a discharging unit configured to discharge the battery; and
a control unit configured to control the charging unit so that the battery is charged with a plurality of charging sections, and to control the discharging unit so that a first discharging pulse is applied between an n−1th charging section and an nth charging section, where n is a natural number greater than or equal to 2, and a second discharging pulse is applied between the nth charging section and an n+1th charging section,
wherein the control unit is configured to control the discharging unit so that a discharging rate of the second discharging pulse is less than a discharging rate of the first discharging pulse.

8. The battery charging apparatus according to claim 7,
wherein the control unit is configured to control the discharging unit so that a time during which the second discharging pulse is applied is longer than a time during which the first discharging pulse is applied.

9. The battery charging apparatus according to claim 8,
wherein the control unit is configured to control the discharging rate of the first or second discharging pulse and the time during which the first or second discharging pulse is applied so that a discharging amount of the second discharging pulse is less than or equal to a discharging amount of the first discharging pulse.

10. The battery charging apparatus according to claim 7,
wherein the control unit is configured to control the charging unit so that charging environments of the plurality of charging sections are variably set using a preset target SOC, and
wherein the target SOC is estimated as a SOC value at which lithium is precipitated based on a change in characteristic data of the battery according to charging.

11. The battery charging method according to claim 1, wherein discharging according to the first discharging section is performed until a preset first condition is met, and discharging according to the second discharging section is performed until a preset second condition is met, the first and second preset conditions including any of a discharging time and a state of charge (SOC) of the battery.

12. The battery charging method according to claim 1, wherein, for each of the plurality of charging sections, charging is performed until a target SOC is reached for each respective charging section.

13. The battery charging method according to claim 1, wherein a state of charge (SOC) of the battery after the n+1th charging section is greater than a state of charge (SOC) of the battery after the nth charging section, for each of the plurality of charging sections performed in the charging process.

14. The battery charging apparatus according to claim 7, wherein the control unit is configured to control the charging unit so that a charging rate of the nth charging section is less than a charging rate of the n−1th charging section.

15. The battery charging apparatus according to claim 10, wherein the control unit is configured to control the charging unit so that the charging environments of the plurality of charging sections include at least one of a length of each section of the plurality of charging sections and a charging rate of each section of the plurality of charging sections.

16. The battery charging apparatus according to claim 7, wherein the control unit is configured to control the discharging unit so that discharging according to the first discharging section is performed until a preset first condition is met, and discharging according to the second discharging section is performed until a preset second condition is met, the first and second preset conditions including any of a discharging time and a state of charge (SOC) of the battery.

17. The battery charging apparatus according to claim 7, wherein the control unit is configured to control the charging unit, so that for each of the plurality of charging sections, charging is performed until a target SOC is reached for each respective charging section.

18. The battery charging apparatus according to claim 7, wherein the control unit is configured to control the charging unit so that a state of charge (SOC) of the battery after the n+1th charging section is greater than a state of charge (SOC) of the battery after the nth charging section, for each of the plurality of charging sections performed.
